(19) United States
(12) Patent Application Publication
(10) Pub. No.: US 2026/0316614 A1
(43) Pub. Date: Oct. 15, 2026

(54) SYSTEMS AND METHODS FOR CHARGING BATTERY FOR ELECTRIC VEHICLE

(71) Applicant: LG Energy Solution, Ltd., Seoul (KR)

(72) Inventor: KyuHwan KWON, Holland, MI (US)

(73) Assignee: LG Energy Solution, Ltd., Seoul (KR)

(21) Appl. No.: 19/207,908

(22) Filed: May 14, 2025

Related U.S. Application Data
(60) Provisional application No. 63/786,840, filed on Apr. 10, 2025.

(51) Int. Cl. B60L 53/62; B60L 58/15; G01R 31/387; H01M 10/48

(52) U.S. Cl. CPC B60L 53/62; B60L 58/15; G01R 31/387; H01M 10/486; B60L 2240/545; B60L 2240/549

(57) ABSTRACT

A system includes a battery, wherein the battery includes a battery module and one or more controllers configured to generate a charging current for the battery module based on a maximum temperature-based charging current and a maximum capacity-based charging current.

### CROSS-REFERENCE TO RELATED APPLICATION(S)

This application claims the benefit of priority to U.S. Provisional Patent Application No. 63/786,840, filed Apr. 10, 2025, the entirety of which is incorporated by reference herein.

### TECHNICAL FIELD

Various embodiments of the present disclosure relate generally to a battery, and, more particularly, to systems and methods for charging a battery for an electric vehicle.

### BACKGROUND

Commercially available batteries may include nickel-cadmium batteries, nickel-hydrogen batteries, nickel-zinc batteries, lithium batteries and the like, and among them, lithium batteries may be gaining attention due to advantages of charging and discharging freely in the absence of a memory effect, a very low self-discharge rate, and high energy density as compared to nickel-based batteries.

In general, a battery pack mounted in an electric vehicle may include a plurality of cell stacks connected in series or in parallel. In this instance, each cell stack includes one battery cell, or two or more battery cells connected in series. The state of each cell stack included in the battery pack may be monitored by a controller having a battery management system mounted thereon. The controller may output signals for controlling the balancing operation, cooling operation, and discharging operation based on the monitored state from each cell stack.

Battery lifespan may be considered a key technical aspect in an electric vehicle system. A battery power system may control the charging current and charging time of a battery of an electric vehicle. However, some battery power systems may have limited capability for improving battery lifespan.

The present disclosure is directed to overcoming one or more of these above-referenced challenges.

### SUMMARY OF THE DISCLOSURE

In some aspects, the techniques described herein relate to a system including a battery, wherein the battery includes: a battery module; and one or more controllers configured to generate a charging current for the battery module based on a maximum temperature-based charging current and a maximum capacity-based charging current.

In some aspects, the techniques described herein relate to a system, wherein the maximum temperature-based charging current is based on a temperature for the battery module.

In some aspects, the techniques described herein relate to a system, wherein the maximum capacity-based charging current is based on a capacity index for the battery module.

In some aspects, the techniques described herein relate to a system, wherein the maximum temperature-based charging current increases by a set percentage as the temperature for the battery module increases from a first temperature range, the maximum temperature-based charging current is constant at a second temperature range of the temperature for the battery module, and the maximum temperature-based charging current decreases from a third temperature range of the temperature for the battery module.

In some aspects, the techniques described herein relate to a system, wherein: the maximum temperature-based charging current is a first charging current at a first temperature, a second charging current at a second temperature greater than the first temperature, and a third charging current at a third temperature greater than the second temperature, and the first charging current is less than the second charging current, and the third charging current is less than the second charging current.

In some aspects, the techniques described herein relate to a system, wherein: the maximum capacity-based charging current is a first charging current at a first index and a second charging current at a second index greater than the first index, and the first charging current is greater than the second charging current.

In some aspects, the techniques described herein relate to a system, further including: a motor configured to receive power from the battery, wherein the system is provided as a vehicle.

In some aspects, the techniques described herein relate to a method including: determining a maximum temperature-based charging current for a battery; determining a maximum capacity-based charging current for the battery; and generating a charging current for the battery based on the maximum temperature-based charging current and the maximum capacity-based charging current.

In some aspects, the techniques described herein relate to a method, wherein determining the maximum temperature-based charging current includes determining the maximum temperature-based charging current based on a temperature for the battery.

In some aspects, the techniques described herein relate to a method, wherein determining the maximum capacity-based charging current includes determining the maximum capacity-based charging current based on an index for the battery.

In some aspects, the techniques described herein relate to a method, wherein the index is based on a usage of the battery.

In some aspects, the techniques described herein relate to a method, wherein the usage is one or more of a number of charging cycles of the battery or a total time of operation of the battery.

In some aspects, the techniques described herein relate to a method, wherein the index is based on a calendar date.

In some aspects, the techniques described herein relate to a method, wherein generating the charging current includes generating the charging current at a constant current during a charging cycle of the battery.

In some aspects, the techniques described herein relate to a method, wherein the charging cycle includes a constant current charging period and a constant voltage charging period.

In some aspects, the techniques described herein relate to a method, wherein the constant voltage charging period follows the constant current charging period in the charging cycle.

In some aspects, the techniques described herein relate to a method, wherein: generating the charging current includes generating a first charging current for a first charging cycle of the battery and generating a second charging current for a second charging cycle of the battery, the first charging current is different from the second charging current, and a charging time of the first charging cycle is substantially equal to the charging time of the second charging cycle.

In some aspects, the techniques described herein relate to one or more controllers configured to: generate a first charging current for a battery based on a first capacity of the battery; and generate a second charging current for the battery based on a second capacity of the battery, wherein the second capacity is less than the first capacity and the second charging current is less than the first charging current.

In some aspects, the techniques described herein relate to one or more controllers, wherein the one or more controllers are further configured to: determine the first capacity of the battery based on a first index for the battery, and determine the second capacity of the battery based on a second index for the battery.

In some aspects, the techniques described herein relate to one or more controllers, wherein a first index of the battery and a second index of the battery are based on one or more of a usage of the battery or a calendar date.

Additional objects and advantages of the disclosed embodiments will be set forth in part in the description that follows, and in part will be apparent from the description, or may be learned by practice of the disclosed embodiments. The objects and advantages of the disclosed embodiments will be realized and attained by means of the elements and combinations particularly pointed out in the appended claims.

It is to be understood that both the foregoing general description and the following detailed description are exemplary and explanatory only and are not restrictive of the disclosed embodiments, as claimed.

### BRIEF DESCRIPTION OF THE DRAWINGS

The accompanying drawings, which are incorporated in and constitute a part of this specification, illustrate various exemplary embodiments and together with the description, serve to explain the principles of the disclosed embodiments.

FIG. 1 depicts an exemplary system infrastructure for a vehicle including a battery, according to one or more embodiments.

FIG. 2 depicts an exemplary system infrastructure for the battery of FIG. 1 with a controller, according to one or more embodiments.

FIG. 3 depicts an exemplary system infrastructure for the controller of FIG. 2, according to one or more embodiments.

FIG. 4 depicts an exemplary method of charging a battery, according to one or more embodiments.

FIG. 5 depicts an exemplary chart of maximum temperature-based charging currents, according to one or more embodiments.

FIG. 6 depicts an exemplary chart of maximum capacity-based charging currents, according to one or more embodiments.

FIG. 7 depicts an exemplary charging cycle of a battery, according to one or more embodiments.

### DETAILED DESCRIPTION OF EMBODIMENTS

Both the foregoing general description and the following detailed description are exemplary and explanatory only and are not restrictive of the features, as claimed. As used herein, the terms “comprises,” “comprising,” “has,” “having,” “includes,” “including,” or other variations thereof, are intended to cover a non-exclusive inclusion such that a process, method, article, or apparatus that comprises a list of elements does not include only those elements, but may include other elements not expressly listed or inherent to such a process, method, article, or apparatus. In this disclosure, unless stated otherwise, relative terms, such as, for example, “about,” “substantially,” and “approximately” are used to indicate a possible variation of ±10% in the stated value. In this disclosure, unless stated otherwise, any numeric value may include a possible variation of ±10% in the stated value.

The terminology used below may be interpreted in its broadest reasonable manner, even though it is being used in conjunction with a detailed description of certain specific examples of the present disclosure. Indeed, certain terms may even be emphasized below; however, any terminology intended to be interpreted in any restricted manner will be overtly and specifically defined as such in this Detailed Description section.

Various embodiments of the present disclosure relate generally to a battery, and, more particularly, to a charging method for a battery for an electric vehicle.

Battery lifespan may be considered a key technical aspect in an electric vehicle system. A battery power system may control a charging current, a charging voltage, and a time for charging of a battery system of an electric vehicle. Some systems may control a voltage in order to manage battery lifespan. Some systems may increase charge time as a result of controlling a voltage in order to manage battery lifespan. Some systems may not control a charging current, a charging voltage, or a time for charging of a battery system of an electric vehicle in response to a temperature, for example an ambient temperature, a temperature of a vehicle, or a temperature of a battery. Some systems may not control a charging current, a charging voltage, or a time for charging of a battery system of an electric vehicle in response to the health of a battery, for example an age of a battery, usage level of a battery over time, or a lifespan of a battery.

One or more embodiments provide systems or methods that may control a current in order to manage battery lifespan. Systems or methods may keep the overall charge time of a battery the same (or substantially equal) throughout a lifespan of a battery, while controlling a charging current of the battery. Systems or methods may control a charging current, a charging voltage, or a time for charging of a battery system of an electric vehicle in response to a temperature, for example an ambient temperature, a temperature of a vehicle, or a temperature of a battery. One or more embodiments may provide systems or methods that may be configured to control a charging current, a charging voltage, or a time for charging of a battery system of an electric vehicle in response to a capacity of a battery, for example an age of a battery, usage level of a battery over time, or a lifespan of a battery.

One or more embodiments may provide systems or methods with a table where charging limits may be determined. The charging limits may be referenced and incorporated into a varied charging current for a charging of a battery.

One or more embodiments may provide systems or methods that may implement a formula that may determine charging current. For example, one or more embodiments may provide a formula or algorithm that stipulates:
If a value of a temperature-based high voltage battery maximum charging current allowed is less than a maximum capacity-based charging current (for example 10.8 A=estimated capacity*20 Amperes/Capacity at battery beginning of life), Then, use temperature-based high voltage battery maximum charging current allowed,
Else, use maximum capacity-based charging current.

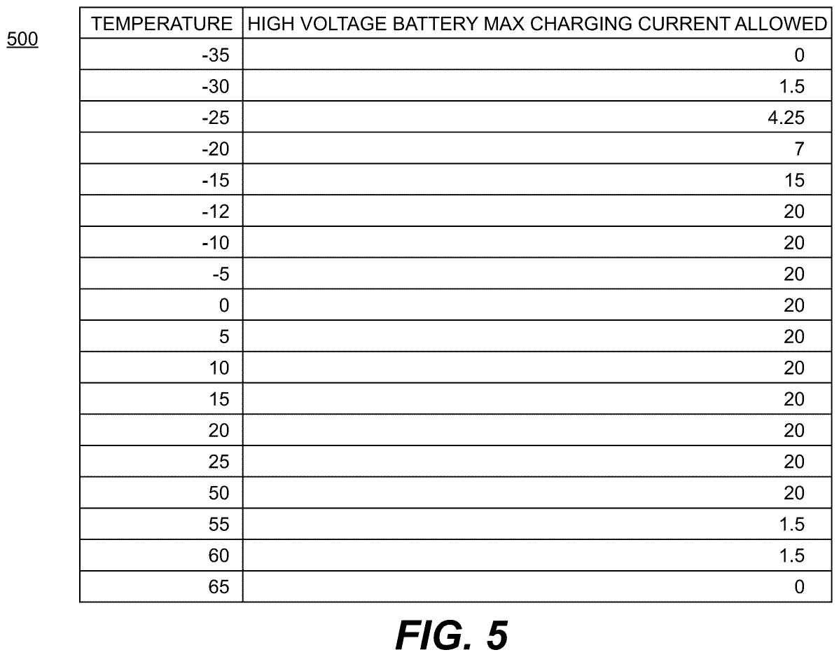

10.8 A may be a minimum charging current which may keep the battery warming capability (even if started from −20 degrees Celsius, with the charging current, battery may warm up quickly to the temperature zone where maximum current is allowed (for example −12 C in FIG. 5).

One or more embodiments may provide a capacity estimation which may be dynamic such that the estimation may include not only calendar based presets but may also include individual capacity throughout the life of a battery in an actual customer's unique usage profile. Capacity estimation may include calendar based and dynamic estimation. Vehicles may be in a less than optimal case, for example, having not been driven in over a year. A calendar based estimation may include methods to estimate the capacity of the battery.

One or more embodiments may provide maintaining longer battery life by not stressing the battery, as Solid Electrolyte interphase may grow faster at high c-rate charging. Capacity reduction may be slower (for example, less aging). Systems or methods may provide safety from any swelling or any potential short circuit by li-plating. Solid electrolyte interphase may include increased cell resistance which may also lead to aging (less capacity).

One or more embodiments may provide a battery which provides for a 1 C charging rate at a beginning of life of the battery. Systems or methods may include reducing the li-plating while keeping customer runs at the same charging time (for example, including at beginning of life), 2 hours at BOL (“beginning of life”) with 1 C rate charging, 2 hour at EOL (“end of life”) with 0.5 C rate (which may include 1 C due to capacity of cell degradated to 50% from beginning of life). Systems or methods may include the same c-rate charging. Some systems may result in 2 C rate charging as the system may not take capacity into consideration.

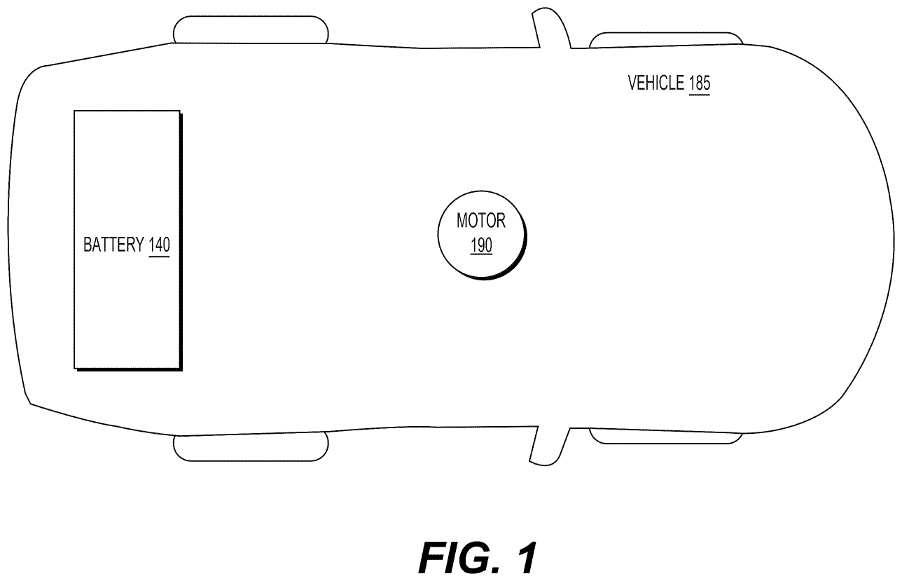

FIG. 1 depicts an exemplary system infrastructure for a vehicle including a battery, according to one or more embodiments. As shown in FIG. 1, vehicle 185 may include a motor 190, and a battery 140. Battery 140 may be a battery pack. Battery 140 may include one or more batteries. Battery 140 may include individual battery cells and a controller configured to control either a charging of the battery 140 or a discharging of the battery 140. The battery 140 may provide electrical power to a motor 190. Vehicle 185 may include diesel powered vehicles, gasoline powered vehicles, hydrogen powered vehicles, electric powered vehicles, or hybrid vehicles.

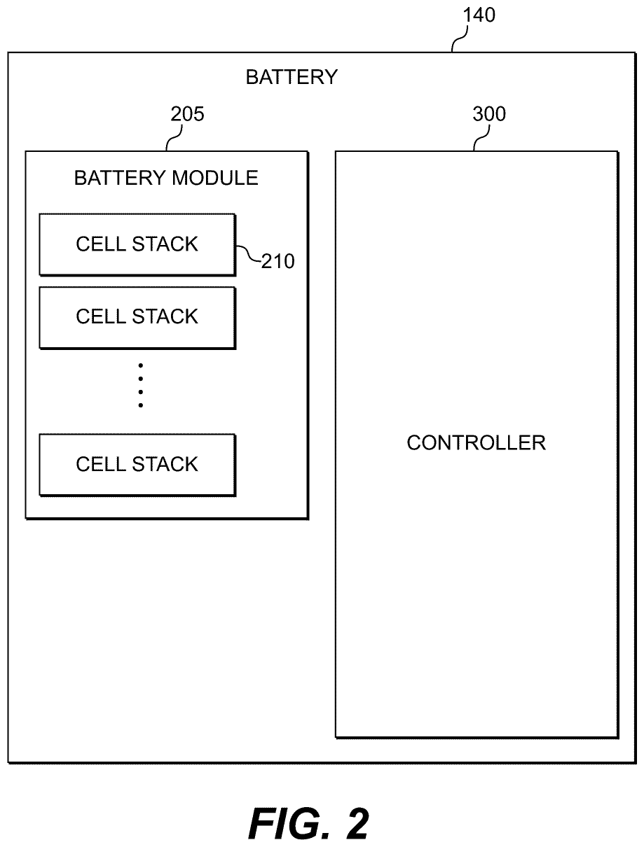

FIG. 2 depicts an exemplary system infrastructure for the battery of FIG. 1 with a controller, according to one or more embodiments. Battery 140 may include a battery module 205 and controller 300. Battery module 205 may include a plurality of cell stacks, including cell stack 210.

Battery 140 may include a battery pack. Battery 140 may include an overcharge prevention apparatus. Overcharge prevention apparatus may include a voltage measuring unit, a current regulating unit, and a controller 300, and optionally may further include at least one of a disconnecting unit, a current measuring unit, and a cooling unit. Additionally, when the overcharge prevention apparatus includes a disconnecting unit, a discharge inducing unit may be included.

The plurality of cell stacks, which may include cell stack 210, may be connected in series and installed on a high current path between two power terminals of battery 140. A voltage measuring unit may measure the voltage of each cell stack 210, and may generate a first monitoring signal indicating the measured voltage. The first monitoring signal generated by the voltage measuring unit may be transmitted to the controller. The current regulating unit may be configured to selectively provide each cell stack 210 with bypass paths connected in parallel. Current regulating unit may provide bypass paths individually to the plurality of cell stacks, which may include for example cell stack 210.

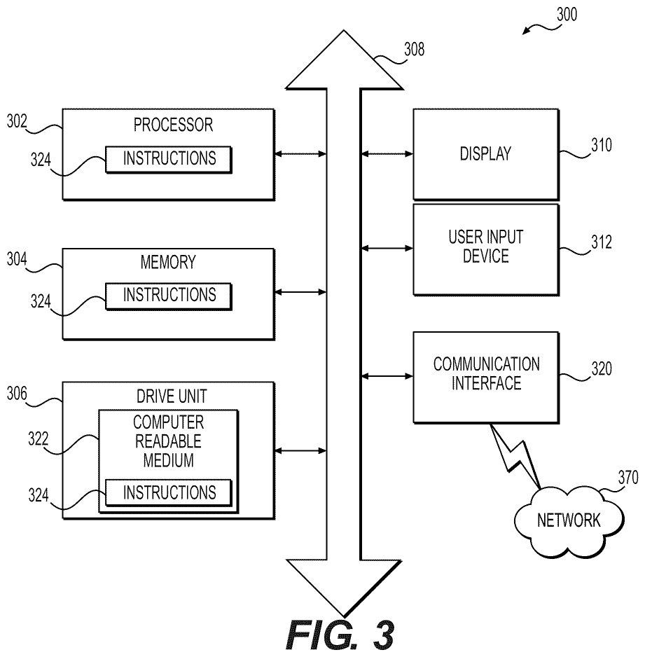

FIG. 3 depicts an exemplary system infrastructure for the controller of FIG. 2, according to one or more embodiments.

FIG. 3 depicts an implementation of a computer system that may execute techniques presented herein, according to one or more embodiments. FIG. 3 and the following discussion provide a brief, general description of a suitable computing environment in which the present disclosure may be implemented. In one embodiment, any of the disclosed systems, methods, and/or graphical user interfaces may be executed by or implemented by a computing system consistent with or similar to that depicted in FIG. 3. Although not required, aspects of the present disclosure are described in the context of computer-executable instructions, such as routines executed by a data processing device, e.g., a server computer, wireless device, and/or personal computer. Those skilled in the relevant art will appreciate that aspects of the present disclosure can be practiced with other communications, data processing, or computer system configurations, including: Internet appliances, hand-held devices (including personal digital assistants (“PDAs”)), wearable computers, all manner of cellular or mobile phones (including Voice over IP (“VoIP”) phones), dumb terminals, media players, gaming devices, virtual reality devices, multi-processor systems, microprocessor-based or programmable consumer electronics, set-top boxes, network PCs, mini-computers, mainframe computers, and the like. Indeed, the terms “computer,” “server,” and the like, are generally used interchangeably herein, and refer to any of the above devices and systems, as well as any data processor.

Aspects of the present disclosure may be embodied in a special purpose computer and/or data processor that is specifically programmed, configured, and/or constructed to perform one or more of the computer-executable instructions explained in detail herein. While aspects of the present disclosure, such as certain functions, are described as being performed exclusively on a single device, the present disclosure may also be practiced in distributed environments where functions or modules are shared among disparate processing devices, which are linked through a communications network, such as a Local Area Network (“LAN”), Wide Area Network (“WAN”), and/or the Internet. Similarly, techniques presented herein as involving multiple devices may be implemented in a single device. In a distributed computing environment, program modules may be located in both local and/or remote memory storage devices.

Aspects of the present disclosure may be stored and/or distributed on non-transitory computer-readable media, including magnetically or optically readable computer discs, hard-wired or preprogrammed chips (e.g., EEPROM semiconductor chips), nanotechnology memory, biological memory, or other data storage media. Alternatively, computer implemented instructions, data structures, screen displays, and other data under aspects of the present disclosure may be distributed over the Internet and/or over other networks (including wireless networks), on a propagated signal on a propagation medium (e.g., an electromagnetic wave(s), a sound wave, etc.) over a period of time, and/or they may be provided on any analog or digital network (packet switched, circuit switched, or other scheme).

The controller 300 may include a set of instructions that can be executed to cause the controller 300 to perform any one or more of the methods or computer-based functions disclosed herein. The controller 300 may operate as a standalone device or may be connected, e.g., using a network, to other computer systems or peripheral devices.

In a networked deployment, the controller 300 may operate in the capacity of a server or as a client in a server-client user network environment, or as a peer computer system in a peer-to-peer (or distributed) network environment. The controller 300 can also be implemented as or incorporated into various devices, such as a personal computer (PC), a tablet PC, a set-top box (STB), a personal digital assistant (PDA), a mobile device, a palmtop computer, a laptop computer, a desktop computer, a communications device, a wireless telephone, a land-line telephone, a control system, a camera, a scanner, a facsimile machine, a printer, a pager, a personal trusted device, a web appliance, a network router, switch or bridge, or any other machine capable of executing a set of instructions (sequential or otherwise) that specify actions to be taken by that machine. In a particular implementation, the controller 300 can be implemented using electronic devices that provide voice, video, or data communication. Further, while the controller 300 is illustrated as a single system, the term “system” shall also be taken to include any collection of systems or sub-systems that individually or jointly execute a set, or multiple sets, of instructions to perform one or more computer functions.

As illustrated in FIG. 3, the controller 300 may include a processor 302, e.g., a central processing unit (CPU), a graphics processing unit (GPU), or both. The processor 302 may be a component in a variety of systems. For example, the processor 302 may be part of a standard computer. The processor 302 may be one or more general processors, digital signal processors, application specific integrated circuits, field programmable gate arrays, servers, networks, digital circuits, analog circuits, combinations thereof, or other now known or later developed devices for analyzing and processing data. The processor 302 may implement a software program, such as code generated manually (i.e., programmed).

The controller 300 may include a memory 304 that can communicate via a bus 308. The memory 304 may be a main memory, a static memory, or a dynamic memory. The memory 304 may include, but is not limited to computer readable storage media such as various types of volatile and non-volatile storage media, including but not limited to random access memory, read-only memory, programmable read-only memory, electrically programmable read-only memory, electrically erasable read-only memory, flash memory, magnetic tape or disk, optical media and the like. In one implementation, the memory 304 includes a cache or random-access memory for the processor 302. In alternative implementations, the memory 304 is separate from the processor 302, such as a cache memory of a processor, the system memory, or other memory. The memory 304 may be an external storage device or database for storing data. Examples include a hard drive, compact disc (“CD”), digital video disc (“DVD”), memory card, memory stick, floppy disc, universal serial bus (“USB”) memory device, or any other device operative to store data. The memory 304 is operable to store instructions executable by the processor 302. The functions, acts or tasks illustrated in the figures or described herein may be performed by the processor 302 executing the instructions stored in the memory 304. The functions, acts or tasks are independent of the particular type of instructions set, storage media, processor or processing strategy and may be performed by software, hardware, integrated circuits, firm-ware, micro-code and the like, operating alone or in combination. Likewise, processing strategies may include multiprocessing, multitasking, parallel processing and the like.

As shown, the controller 300 may further include a display 310, such as a liquid crystal display (LCD), an organic light emitting diode (OLED), a flat panel display, a solid-state display, a cathode ray tube (CRT), a projector, a printer or other now known or later developed display device for outputting determined information. The display 310 may act as an interface for the user to see the functioning of the processor 302, or specifically as an interface with the software stored in the memory 304 or in the drive unit 306.

Additionally or alternatively, the controller 300 may include an input device 312 configured to allow a user to interact with any of the components of controller 300. The input device 312 may be a number pad, a keyboard, or a cursor control device, such as a mouse, or a joystick, touch screen display, remote control, or any other device operative to interact with the controller 300.

The controller 300 may also or alternatively include drive unit 306 implemented as a disk or optical drive. The drive unit 306 may include a computer-readable medium 322 in which one or more sets of instructions 324, e.g. software, can be embedded. Further, the instructions 324 may embody one or more of the methods or logic as described herein. The instructions 324 may reside completely or partially within the memory 304 and/or within the processor 302 during execution by the controller 300. The memory 304 and the processor 302 also may include computer-readable media as discussed above.

In some systems, a computer-readable medium 322 includes instructions 324 or receives and executes instructions 324 responsive to a propagated signal so that a device connected to a network 370 can communicate voice, video, audio, images, or any other data over the network 370. Further, the instructions 324 may be transmitted or received over the network 370 via a communication port or interface 320, and/or using a bus 308. The communication port or interface 320 may be a part of the processor 302 or may be a separate component. The communication port or interface 320 may be created in software or may be a physical connection in hardware. The communication port or interface 320 may be configured to connect with a network 370, external media, the display 310, or any other components in controller 300, or combinations thereof. The connection with the network 370 may be a physical connection, such as a wired Ethernet connection or may be established wirelessly as discussed below. Likewise, the additional connections with other components of the controller 300 may be physical connections or may be established wirelessly. The network 370 may alternatively be directly connected to a bus 308.

While the computer-readable medium 322 is shown to be a single medium, the term “computer-readable medium” may include a single medium or multiple media, such as a centralized or distributed database, and/or associated caches and servers that store one or more sets of instructions. The term “computer-readable medium” may also include any medium that is capable of storing, encoding, or carrying a set of instructions for execution by a processor or that cause a computer system to perform any one or more of the methods or operations disclosed herein. The computer-readable medium 322 may be non-transitory, and may be tangible.

The computer-readable medium 322 can include a solid-state memory such as a memory card or other package that houses one or more non-volatile read-only memories. The computer-readable medium 322 can be a random-access memory or other volatile re-writable memory. Additionally or alternatively, the computer-readable medium 322 can include a magneto-optical or optical medium, such as a disk or tapes or other storage device to capture carrier wave signals such as a signal communicated over a transmission medium. A digital file attachment to an e-mail or other self-contained information archive or set of archives may be considered a distribution medium that is a tangible storage medium. Accordingly, the disclosure is considered to include any one or more of a computer-readable medium or a distribution medium and other equivalents and successor media, in which data or instructions may be stored.

In an alternative implementation, dedicated hardware implementations, such as application specific integrated circuits, programmable logic arrays and other hardware devices, can be constructed to implement one or more of the methods described herein. Applications that may include the apparatus and systems of various implementations can broadly include a variety of electronic and computer systems. One or more implementations described herein may implement functions using two or more specific interconnected hardware modules or devices with related control and data signals that can be communicated between and through the modules, or as portions of an application-specific integrated circuit. Accordingly, the present system encompasses software, firmware, and hardware implementations.

The controller 300 may be connected to a network 370. The network 370 may define one or more networks including wired or wireless networks. The wireless network may be a cellular telephone network, an 802.11, 802.16, 802.20, or WiMAX network. Further, such networks may include a public network, such as the Internet, a private network, such as an intranet, or combinations thereof, and may utilize a variety of networking protocols now available or later developed including, but not limited to TCP/IP based networking protocols. The network 370 may include wide area networks (WAN), such as the Internet, local area networks (LAN), campus area networks, metropolitan area networks, a direct connection such as through a Universal Serial Bus (USB) port, or any other networks that may allow for data communication. The network 370 may be configured to couple one computing device to another computing device to enable communication of data between the devices. The network 370 may generally be enabled to employ any form of machine-readable media for communicating information from one device to another. The network 370 may include communication methods by which information may travel between computing devices. The network 370 may be divided into sub-networks. The sub-networks may allow access to all of the other components connected thereto or the sub-networks may restrict access between the components. The network 370 may be regarded as a public or private network connection and may include, for example, a virtual private network or an encryption or other security mechanism employed over the public Internet, or the like.

In accordance with various implementations of the present disclosure, the methods described herein may be implemented by software programs executable by a computer system. Further, in an exemplary, non-limited implementation, implementations can include distributed processing, component/object distributed processing, and parallel processing. Alternatively, virtual computer system processing can be constructed to implement one or more of the methods or functionality as described herein.

Although the present specification describes components and functions that may be implemented in particular implementations with reference to particular standards and protocols, the disclosure is not limited to such standards and protocols. For example, standards for Internet and other packet switched network transmission (e.g., TCP/IP, UDP/IP, HTML, HTTP) represent examples of the state of the art. Such standards are periodically superseded by faster or more efficient equivalents having essentially the same functions. Accordingly, replacement standards and protocols having the same or similar functions as those disclosed herein are considered equivalents thereof.

It will be understood that the steps of methods discussed are performed in one embodiment by an appropriate processor (or processors) of a processing (i.e., computer) system executing instructions (computer-readable code) stored in storage. It will also be understood that the disclosure is not limited to any particular implementation or programming technique and that the disclosure may be implemented using any appropriate techniques for implementing the functionality described herein. The disclosure is not limited to any particular programming language or operating system.

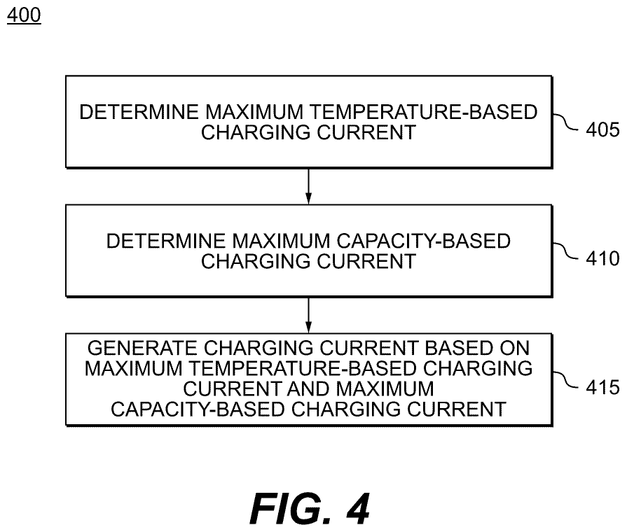

FIG. 4 depicts an exemplary method of charging a battery, according to one or more embodiments. The method 400 of charging a battery 140 may control a current input of the battery 140. As shown in FIG. 4, controller 300 may determine maximum temperature-based charging current (operation 405). Controller 300 may determine a maximum capacity-based charging current (operation 410). Controller 300 may perform one or more of operation 405 or operation 410 at a start-up of battery 140, when detecting a charging operation of battery 140, or other event. Controller 300 may generate a charging current for battery 140 based on the maximum temperature-based charging current from operation 405 and the maximum capacity-based charging current from operation 410 (operation 415). For example, controller 300 may generate a charging current for battery 140 based on the lesser value among the maximum temperature-based charging current from operation 405 and the maximum capacity-based charging current from operation 410.

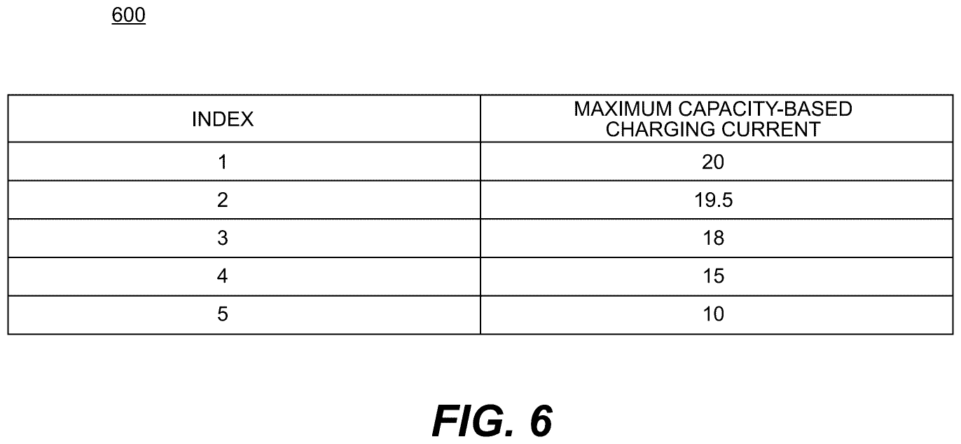

The maximum temperature-based charging current of operation 405 may include, for example, the values depicted in FIG. 5. The maximum capacity-based charging current of operation 410 may include, for example, the values depicted in FIG. 6. Method 400 may limit a charging current of battery 140 in order to extend the life of battery 140, reduce harm to battery 140, or improve functionality of battery 140. Method 400 may decrease a charging current of a battery 140 over a time period while maintaining a charging time substantially the same over the time period. For example, method 400 may include charging battery 140 at 20 amperes for two hours during a first time period, and charging battery 140 at 10 amperes for two hours during a second time period.

FIG. 5 depicts an exemplary chart of maximum temperature-based charging currents, according to one or more embodiments. Chart 500 may include a range of values for high voltage battery maximum charging current allowed at a given temperature. Chart 500 may include a range of values for maximum temperature-based charging current. For example, when a battery is at a temperature −35 degrees Celsius, chart 500 may depict the maximum charging current allowed may be 0 amperes. Chart 500 may include a range of temperature values including a maximum allowed charging current of 0 amperes at −35 degrees Celsius, 1.5 amperes at −30 degrees Celsius, 4.25 amperes at −25 degrees Celsius, 7 amperes at −20 degrees Celsius, 15 amperes at −15 degrees Celsius, 20 amperes at a range of −12 degrees Celsius to 50 degrees Celsius, 1.5 amperes at a range of 55 degrees Celsius to 60 degrees Celsius, and 0 amperes at 65 degrees Celsius. For example, the maximum temperature-based charging current may be a first charging current 7 A at a first temperature −20 degrees Celsius, a second charging current 20 A at a second temperature 0 degrees Celsius greater than the first temperature −20 degrees Celsius, and a third charging current 1.5 A at a third temperature 55 degrees Celsius greater than the second temperature 0 degrees Celsius, where the first charging current 7 A is less than the second charging current 20 A, and the third charging current 1.5 A is less than the second charging current 20 A. As depicted in FIG. 5, the first charging current is different from the second charging current, for example.

The values depicted in chart 500 may include values utilized in an algorithm configured for an improved lifecycle or lifespan of battery 140 in vehicle 185. For example, the values of chart 500 may include values used in method 400. The values of chart 500 may include values used by controller 300 to determine a maximum temperature-based charging current (for example, operation 410). A maximum charging current may be limited at temperatures in order to extend the life of battery 140, reduce harm to battery 140, or improve functionality of battery 140. Temperature of battery 140 may increase as battery 140 charges. A maximum charging current may increase as the temperature increases to a nominal value range. A maximum charging current may decrease as the temperature increases above a nominal value range. An algorithm configured for an improved lifecycle or lifespan of battery 140 in vehicle 185 may or may not use the values depicted in chart 500. For example, an algorithm may determine a maximum temperature-based charging current (for example, operation 410) based on a set of values where the maximum temperature-based charging current increases by a set percentage as temperature increases from a lower temperature bound for a battery to an operating temperature for the battery, may be constant at an operating temperature for the battery, and may decrease from the operating temperature to an upper temperature bound for the battery.

FIG. 6 depicts an exemplary chart of maximum capacity-based charging currents, according to one or more embodiments. Chart 600 may include a range of values for maximum capacity-based charging current. Chart 600 may include a range of values for maximum capacity-based charging current that decreases as an indexed value increases. For example, chart 600 may include a range of indexed values that increases from 1 to 5 and may correspond to a decrease in maximum capacity-based charging current allowed. Indexed values may include one or more of usage-based values, or calendar-based values. Usage-based values may include, for example, a number of charging cycles for a battery, or a total time of operation of the battery. For example, maximum capacity-based charging current may decrease as the number of charging cycles increases. Decreasing a maximum capacity-based charging current as the number of charging cycles increases may decrease a degradation of a battery. Calendar-based values may include a calendar date or a period of calendar dates, for example, decades, years, months, weeks, or days. For example, maximum capacity-based charging current may decrease as the years of use for a battery increase. Indexed values may include a combination of usage-based values and calendar-based values. For example, indexed values may include number of charging cycles at year one, or number of charging cycles at year two.

The values depicted in chart 600 may include values utilized in an algorithm configured for an improved lifecycle or lifespan of battery 140 in vehicle 185. For example, the values of chart 600 may include values utilized to implement method 400. The values of chart 600 may include values used by controller 300 to determine a maximum capacity-based charging current (for example, operation 410). A maximum charging current value may be limited at increasing indexed values in order to extend the life of battery 140, reduce harm to battery 140, or improve functionality of battery 140. A maximum charging current value may decrease as the indexed value increases.

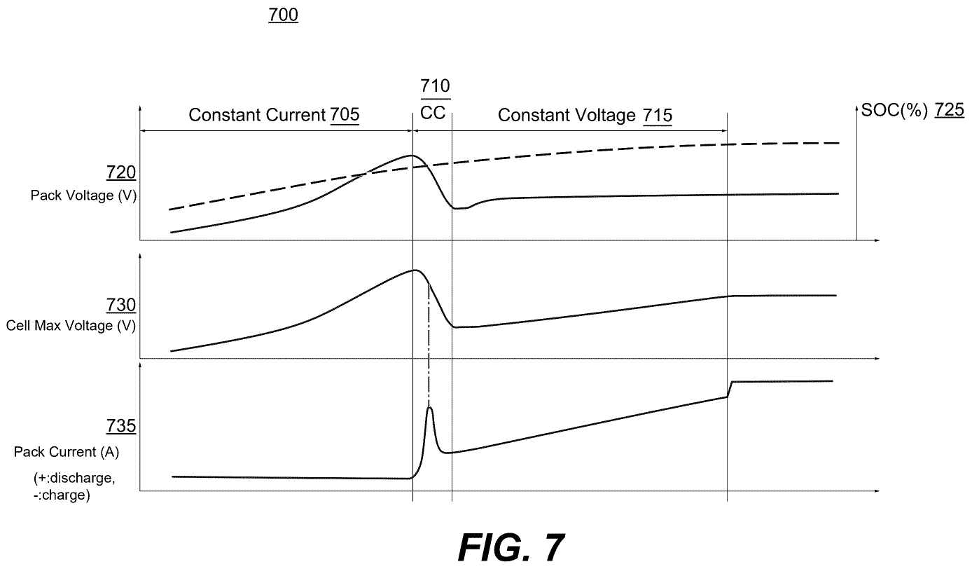

FIG. 7 depicts an exemplary charging cycle of a battery, according to one or more embodiments. Graph 700 includes pack voltage 720, cell maximum voltage 730, and pack current 735. In a constant current 705 period, pack voltage 720 may increase, and cell maximum voltage 730 may increase, while pack current 735 may stay substantially constant. In a constant current 705 period, a state of charge of a battery or SOC 725 may increase. SOC 725 may include a percentage from zero to one hundred percent. In a CC 710 period, a change from a constant current 705 period to a constant voltage 715 period may begin, and a current may be constant during this period. In a CC 710 period, pack voltage 720 may decrease, cell maximum voltage 730 may decrease, pack current 735 may increase and decrease, and SOC 725 may increase. In a constant voltage 715 period, pack voltage 720 may stay substantially constant, cell maximum voltage 730 may increase, pack current 735 may increase, and SOC 725 may increase. Graph 700 may depict implementation of an algorithm configured for diagnostic improvement for an improved battery lifecycle or lifespan in an electric vehicle. For example, constant current 705 period of graph 700 may depict a period where method 400 has been implemented.

Other embodiments of the disclosure will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A system comprising a battery, wherein the battery includes:
a battery module; and
one or more controllers configured to generate a charging current for the battery module based on a maximum temperature-based charging current and a maximum capacity-based charging current.

2. The system of claim 1, wherein the maximum temperature-based charging current is based on a temperature for the battery module.

3. The system of claim 1, wherein the maximum capacity-based charging current is based on a capacity index for the battery module.

4. The system of claim 2, wherein the maximum temperature-based charging current increases by a set percentage as the temperature for the battery module increases from a first temperature range, the maximum temperature-based charging current is constant at a second temperature range of the temperature for the battery module, and the maximum temperature-based charging current decreases from a third temperature range of the temperature for the battery module.

5. The system of claim 1, wherein:
the maximum temperature-based charging current is a first charging current at a first temperature, a second charging current at a second temperature greater than the first temperature, and a third charging current at a third temperature greater than the second temperature, and
the first charging current is less than the second charging current, and the third charging current is less than the second charging current.

6. The system of claim 1, wherein:
the maximum capacity-based charging current is a first charging current at a first index and a second charging current at a second index greater than the first index, and
the first charging current is greater than the second charging current.

7. The system of claim 1, further comprising:
a motor configured to receive power from the battery,
wherein the system is provided as a vehicle.

8. A method comprising:
determining a maximum temperature-based charging current for a battery;
determining a maximum capacity-based charging current for the battery; and
generating a charging current for the battery based on the maximum temperature-based charging current and the maximum capacity-based charging current.

9. The method of claim 8, wherein determining the maximum temperature-based charging current includes determining the maximum temperature-based charging current based on a temperature for the battery.

10. The method of claim 8, wherein determining the maximum capacity-based charging current includes determining the maximum capacity-based charging current based on an index for the battery.

11. The method of claim 10, wherein the index is based on a usage of the battery.

12. The method of claim 11, wherein the usage is one or more of a number of charging cycles of the battery or a total time of operation of the battery.

13. The method of claim 10, wherein the index is based on a calendar date.

14. The method of claim 8, wherein generating the charging current includes generating the charging current at a constant current during a charging cycle of the battery.

15. The method of claim 14, wherein the charging cycle includes a constant current charging period and a constant voltage charging period.

16. The method of claim 15, wherein the constant voltage charging period follows the constant current charging period in the charging cycle.

17. The method of claim 8, wherein:
generating the charging current includes generating a first charging current for a first charging cycle of the battery and generating a second charging current for a second charging cycle of the battery,
the first charging current is different from the second charging current, and
a charging time of the first charging cycle is substantially equal to the charging time of the second charging cycle.

18. One or more controllers configured to:
generate a first charging current for a battery based on a first capacity of the battery; and
generate a second charging current for the battery based on a second capacity of the battery, wherein the second capacity is less than the first capacity and the second charging current is less than the first charging current.

19. The one or more controllers of claim 18, wherein the one or more controllers are further configured to:
determine the first capacity of the battery based on a first index for the battery, and
determine the second capacity of the battery based on a second index for the battery.

20. The one or more controllers of claim 18, wherein a first index of the battery and a second index of the battery are based on one or more of a usage of the battery or a calendar date.
